(19) United States
(12) Patent Application Publication
(10) Pub. No.: US 2019/0233941 A1
(43) Pub. Date: Aug. 1, 2019

(54) APPARATUS FOR COATING PARTICLES, AND PROCESS

(71) Applicant: BASF SE, Ludwigshafen am Rhein (DE)

(72) Inventors: Tillmann LIEBSCH, Ludwigshafen (DE); Frank KLEINE JAEGER, Ludwigshafen (DE); Daniel SILBERNAGEL, Ludwigshafen (DE); Stefan STREGE, Ludwigshafen (DE)

(73) Assignee: BASF SE, Ludwigshafen am Rhein (DE)

(21) Appl. No.: 16/318,204

(22) PCT Filed: Jul. 17, 2017
(86) PCT No.: PCT/EP2017/067962

§ 371 Date: Jan. 16, 2019

(30) Foreign Application Priority Data
Jul. 27, 2016 (EP) 16181435.5

(51) Int. Cl. C23C 16/455; C23C 16/44; C23C 16/52; H01M 4/525; H01M 4/505; H01M 4/36

(52) U.S. Cl. CPC C23C 16/45551; C23C 16/4417; C23C 16/52; H01M 10/052; H01M 4/505; H01M 4/366; H01M 4/525

(57) ABSTRACT

The present invention relates to an apparatus for coating particles by atomic layer deposition comprising (a) a first reactor capable of bringing particles in contact with a first reactive gas and (b) a second reactor capable of bringing particles in contact with a second reactive gas, wherein the first and the second reactor are separated by a first and a second gas lock and the particles can be conveyed from the first reactor through the first gas lock to the second reactor and at the same time the particles can be conveyed from the second reactor through the second gas lock to the first reactor.

Atomic layer deposition (ALD) is an attractive method of coating materials as high control over the coating thickness is possible. Also, the quality of very thin coatings is often much higher than those made with other methods. The ALD principles are described in detail by George (Chemical Reviews 110 (2010), 111-131). Although ALD is known for more than three decades, industrial applicability is still limited. One of the reasons is that high throughput methods have been unavailable until recent years. Formerly, the substrate to be coated has been put into a vacuum chamber where it was reacted with a first reactive gas. Its residuals were removed by evacuation before the second reactive gas was introduced. This process takes a long time, in particular if particles of small particle size are to be coated. Recently, continuous processes have been introduced which can operate at atmospheric pressures.

US 2015/0 079 310 A1 discloses an apparatus for coating particles in an ALD process. The particles are conveyed on a belt over which a first reactive gas and then a second reactive gas flows.

US 2015/0 031 157 A1 discloses a similar apparatus. Here, the particles are blown over a speed adjustment member and are thereby overtaken by a flow of reactive gases.

However, in both approaches, the separation of the reactive gases remains a challenge which limits the material throughput. If the reactive gases come in contact with each other, the product becomes contaminated with side product and also the apparatus can be blocked by undesired deposits. Furthermore, the slowest reaction limits the whole process, for example if all gas introduction zones are of the same dimension and the first reactive gas needs much more time for the reaction than the second reactive gas.

U.S. Pat. No. 9,284,643 B2 discloses an apparatus for coating particles in an ALD process, wherein the particles fall from one chamber to the next. However, this apparatus is not suitable for large-scale production, particularly if thicker coatings on the particles are required.

It was an object of the present invention to provide an apparatus which allows high material throughput and is flexible such that reaction parameters of the different reactions in an ALD process can be adjusted independently. It was also aimed at an apparatus which can easily be used to make thick coatings with relatively low invest. It was also the aim to provide an apparatus which avoids the contamination of the product and the built-up of undesired deposits inside the apparatus.

These objects were achieved by an apparatus for coating particles by atomic layer deposition comprising

(a) a first reactor capable of bringing particles in contact with a first reactive gas and

(b) a second reactor capable of bringing particles in contact with a second reactive gas,

(c) at least one buffer device located between the first and the second reactor,

wherein the first and the second reactor are separated by a first and a second gas lock and particles can be conveyed from the first reactor through the first gas lock to the second reactor or to a buffer device, and at the same time particles can be conveyed from the second reactor through the second gas lock to the first reactor or to a buffer device.

The present invention further relates to a process for coating particles comprising:

(a) exposing the particles in a first reactor to a first gas which reacts with the surface of the particles and

(b) exposing the particles in a second reactor to a second gas which reacts with the surface of the particles after having reacted with the first gas,

wherein the particles are conveyed from the first reactor to the second reactor or to a buffer device (c) through a first gas lock and from the second to the first reactor or to a buffer device (c) through a second gas lock,

wherein at least one buffer device (c) is involved.

Preferred embodiments of the present invention can be found in the description and the claims. Combinations of different embodiments fall within the scope of the present invention.

Atomic layer deposition (ALD) is sometimes also called atomic layer epitaxy (ALE). If one or more organic compounds are involved in the deposition process, sometimes ALD is also referred to as molecular layer deposition (MLD). In the context of the present invention, ALD shall comprise ALE and MLD regardless of subtle differences associated with these terms.

The apparatus according to the present invention comprises a first and a second reactor, which are capable of bringing particles in contact with a first and a second reactive gas respectively. The first and the second reactor can be the same or different to each other. Preferably, at least one of the first and second reactors is capable of moving the particles relative to each other, more preferably both the first and the second reactor are capable of moving the particles relative to each other, in particular the first and the second reactor are capable of moving the particles relative to each other for a time period sufficient for the reactive gas to react with the surface of the particles, for example for more than 30 seconds or for more than 5 minutes. This reduces the probability that particles stick to each other and generally increases the quality of the coating.

Preferably, the velocity of the relative motion of the particles to each other can be adjusted in the first and/or the second reactor, for example the input of mechanical energy such as mixing speed can be adjusted in the first and/or the second reactor. Preferably, the first and/or the second reactor is capable of keeping the particle in relative motion to each other such that the particles exhibit a Froude number of 0.01 to 20, more preferably 0.05 to 10, in particular 0.1 to 5, such as 0.2 to 0.3 or 1 to 2. Various reactors can be used including mixers such as ploughshare mixer, free fall mixer, or blender; dryers such as paddle dryer, fluidized bed reactors, spouted bed reactors or rotating drums; spatial reactors such as conveying reactors, vibratory equipment, or cascades of mixers, dryers or spatial reactors. Free fall mixers, paddle dryer, or ploughshare mixers are preferred. Among their advantages are high flexibility of parameter tuning and low mechanical stress towards the particles.

According to the present invention, reactive gases are compounds in the gaseous state which are capable of reacting with the surface of particles to form a covalent bond. Usually, the first reactive gas is capable of reacting with the surface of particles after they have been treated with the second reactive gas and the second reactive gas is capable of reacting with the surface of particles after they have been treated with the first reactive gas.

Reactive gases include metal-containing compounds. Metal-containing compounds contain at least one metal atom. Metals include Li, Be, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Cs, Ba, La, Ce, Pr, Nd, Pm, Sm, Eu, Gd, Tb, Dy, Ho, Er, Tm, Yb, Lu, Hf, Ta, W, Re, Os Ir, Pt, Au, Hg, TI, Bi. Preferably, the metal-containing compound is a metal organic compound. These compounds include alkyl metals such as dimethyl zinc, trimethylaluminum; metal alkoxylates such as tetramethoxy orthosilicate, tetra-isopropoxy zirconium or tetra-iso-propoxy titanium; cyclopentadiene complexes like ferrocene, titanocene or di(ethylcycopentadienyl) manganese; metal carbenes such as tantalum-pentaneopentylat or bisimidazolidinylen ruthenium chloride; metal halides such as tantalum pentachloride or titanium tetrachloride; carbon monoxide complexes like hexacarbonyl chromium or tetracarbonyl nickel; amine complexes such as di-(bis-tertbuylamino)-di-(bismethylamino) molybdenum, di-(bis-tertbuylamino)-di-(bismethylamino) tungsten or tetra-dimethylamino titanium; dione complexes such as triacetylacetonato aluminum or bis(2,2,6,6-tetramethyl-3,5-heptanedionato) manganese. Trimethylaluminum is preferred.

Furthermore, reactive gases include plasma like an oxygen plasma or a hydrogen plasma; oxidants like oxygen, oxygen radicals, ozone, nitrous oxide (N₂O), nitric oxide (NO), nitrogendioxide (NO₂) or hydrogen peroxide; reducing agents like hydrogen, hydrogen radicals, hydrogen plasma, ammonia, ammonia radicals, ammonia plasma, hydrazine, N,N-dimethylhydrazine, silane, disilane, trisilane, cyclopentasilane, cyclohexasilane, dimethylsilane, diethylsilane, or trisilylamine; or solvents like water.

Preferably, the first reactive gas is a metal-containing compound and the second reactive gas is water. More preferably, the first reactive gas is trimethylaluminum and the second reactive gas is water.

According to the present invention, the first reactor is capable of bringing particles in contact with a first reactive gas and the second reactor is capable of bringing particles in contact with a second reactive gas. In order to achieve this, a reactor has normally an inlet valve for the first or the second reactive gas. The inlet valve is preferably equipped with a gauge to measure the gas flow rate, for example a flowmeter or a bubbler, and means to control the flow rate of the reactive gas through the inlet valve. Even more preferably, the gauge to measure the gas flow rate and the means to control the flow rate are coupled to a controller, which keeps the set flow rate constant or adjust it to a certain value, for example the amount of excess reactive gas exiting the reactor, which can for example be measured by a mass spectrometer. Such a controller can for example be a computer-based system.

In most cases, the first and the second reactive gas react with each other forming undesirable byproducts which can in some cases block the apparatus. Therefore, it is important to avoid any mixing of the first and the second reactive gas. According to the present invention, the first and the second reactor are separated by a first gas lock and a second gas lock. A gas lock in the context of the present invention comprises at least two means of gas-tight sealing a space between them. These at least two means of gas-tight sealing can be independently opened to allow for a passage of particles from the first reactor to the second or vice versa without a free gas flow from the first to the second reactor or vice versa. Due to the presence of the first and the second gas lock, the first and the second reactor can be operated at different pressures. Means of gas-tight sealing which can be opened include various types of valves such as flaps, gate valves, knife gate valves, rotary valve, ball valves, globe valves, and star valves.

Additionally or alternatively, the pressure in the gas lock can be different to the pressure in the first and the second reactor for a certain time period. For example, the space in the gas lock can be evacuated or purged with an inert gas while the reactive gas atmosphere is maintained in the first and the second reactor. In this way, excess reactive gas can be removed during the passage of the particles from the first reactor to the second reactor or during the passage of the particles from the second reactor to the first reactor.

Often, the reaction rate of the first reactive gas with the surface of the particles is different to the reaction rate of the second reactive gas with the surface of the particles under the same conditions. In order to allow for a continuous process, in the apparatus according to the present invention the temperature, the pressure, and the residence time in the first and the second reactor can be set independent of each other. In this way, the reaction rate in the first reactor and the second reactor can be adjusted such that the particles stream rate in the first and second reactor are the same or substantially the same. In this way, a continuous process can be established with the apparatus according to the present invention.

Preferably, the temperature in the first or second reactor can be set from room temperature to 300° C. Preferably, the temperature difference between the first and the second reactor can be 0 to 300° C. If the temperature difference between the first and the second reactor is large, for example more than 50° C., the apparatus preferably contains a cooler to cool down the particle on their way from the reactor with the higher temperature to the reactor with the lower temperature. If the particles are continuously cycled from the one reactor to the other, the cooler can be in the form of a heat exchanger which transfers heat from the particles at the higher temperature to the particles at the lower temperature.

An ALD process often contains more than one cycle to build up thicker coatings, for example 5 to 1000 cycles. In order to enable multiple ALD cycles the apparatus according to the present invention is capable of transferring the particles back to the first reactor after they have passed the second reactor. The apparatus comprises a first and a second gas lock between the first and the second reactor. In this way, the particles can be transferred continuously from the first reactor to the second through the first gas lock and back to the first through the second gas lock. Typically, each such cycle adds thickness to the coating. In the apparatus according to the present invention, it is possible that the reaction conditions such as temperature, pressure, and/or exposure time are the same over all cycles or that they are changed from one cycle to another.

The apparatus according to the present invention usually comprises means for conveying the particles. Conveying particles can be achieved in various ways including use of gravity such as in a fall tube or on a slide; use of a transport gas such as in a pneumatic conveying or a fluidized bed channel; use of a mechanical conveyor such as in a screw-conveyer, a conveyor belt, a tube chain conveyor, a through chain conveyor, a rotary valve, a bucket elevator, a vibratory feeder or a vibratory bowl feeder. Conveying in a pneumatic conveyor is preferred.

Preferably, the apparatus further contains a device in the gas lock to reduce the amount of residual reactive gas in between the particles. This can be achieved by means of establishing an inert gas flow, preferably in a direction opposite to the particle movement. To further improve the removal of excess inert gas, the particles are kept in motion relative to each other. This can be achieved for example by a down pipe, a zig-zag sifter, a disc centrifuge, fluidized bed, vibrating conveying, or a mixer.

The apparatus further comprises at least one buffer device (c) to store particles exiting from one reactor temporarily before being transferred into the other reactor. Preferably, the apparatus comprises at least two buffer devices (c) to store particles exiting from one reactor before being transferred into the other reactor. One of the advantages is that buffer devices (c) allow for different particle stream rates through the reactors and, in particular if two buffer devices (c) are used, the particle stream rate can be different to the particle stream rates of both reactors, which can improve the removal of any residual reactive gas from the particles before being transferred into the next reactor. Usually, buffer devices (c) comprise an inlet and/or an outlet valve. These vales can form parts of the gas locks which separate the first and the second reactor.

The apparatus according to the present invention is particularly suitable for coating particles at a large scale. Therefore, the apparatus is preferably designed to allow for particle stream rates of at least 10 kg per hour, more preferably at least 20 kg per hour, in particular at least 50 kg per hour, such as at least 100 kg per hour. The particle stream rate in the context of the present invention is the amount of particles per time which passes both the first and the second reactor once. The total amount of particles coated per time can thus typically be obtained by dividing the particle stream rate by the number of ALD cycles which is required for the coating. A possible upper limit is 15 t/h.

Preferably, the apparatus is tight against air entering the interior of the apparatus where the particles are conveyed. Therefore, the apparatus preferably comprises a gas lock for charging the particles into the apparatus and discharging the particles from the apparatus. It is possible to use a single gas lock for this purpose or preferably to use at least two different gas locks. These gas locks are typically not the gas locks which separate the first and the second reactor.

The apparatus according to the present invention is capable of coating particles of various sizes. Preferably, the apparatus is capable of coating particles with a weight average particle diameter in the range of from 0.1 to 1000 μm, more preferably 0.2 to 500 μm, more preferably 0.5 to 200 μm, in particular 1 to 100 μm and even more preferably from 2 to 15 μm. The average particles size is preferably measured by dynamic light scattering according to ISO 22412 (2008), preferably by using the Mie theory.

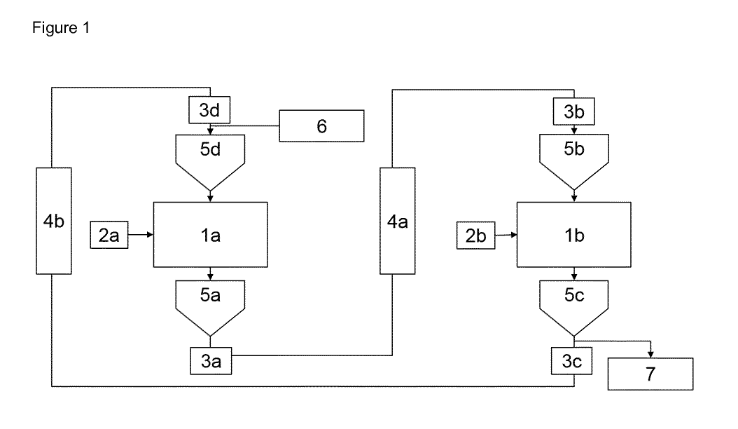

FIG. 1 shows a schematic drawing of a preferred embodiment of the apparatus. The first reactor (1a) and the second reactor (1b) are separated by two gas locks. The first gas lock comprises two valves (3a) and (3b) and a device for keeping the particles in motion (4a) to which preferably a vacuum or a stream of inert gas can be applied. Particles can be transferred from the first reactor (1a) into the first buffer device (5a), then through the valve (3a) and the device for keeping the particles in relative motion to each other (4a) and the valve (3b) into a second buffer device (5b). From there, the particles can be transferred into the second reactor (1b). After exiting the second reactor, the particles can be intermediately stored in a buffer device (5c) before being transferred through the second gas lock comprising the valve (3c), the device for keeping the particles in relative motion to each other (4b) and the valve (3d). The particles can be intermediately stored in the buffer device (5d) before entering the first reactor (1a). The first reactive gas can be injected in the first reactor (1a) by an injector (2a). The second reactive gas can be injected in the second reactor (1b) by an injector (2b). The apparatus can be initially charged with the feed (6), which can, for example, introduce the uncoated particles into the buffer device (5d). After the particles are coated, they are extracted from the apparatus by a discharger (7), for example from the buffer device (5c).

To insert the particles into the reactor, there are various possibilities. Preferably, the buffer device (5d) is charged by suction from a container. For this reason, the buffer device (5d) is preferably equipped with an inlet valve. This inlet valve is typically of sufficient size to allow for quick charging.

In some embodiments, one ALD cycle requires more than two different reactive gases, for example three or more. If three different reactive gases are required, the reactor of the present invention preferably further contains a third reactor which is capable of bringing the particles in contact with the third reactive gas. In this case, the first reactor is separated from the second and third reactor by a gas lock each and the second reactor is separated from the third reactor by another gas lock. In this way, particles can be conveyed from the first reactor to the second reactor through a gas lock, they can be conveyed from the second reactor to the third reactor, and they can be conveyed from the third reactor to the first reactor through a gas lock. At least one buffer device (c) is included. Each reactor may be separated from the next by a buffer device (c) that enables an individual adjustment of the particle flow through each reactor. wherein The analogous situation can be set up if more than three reactive gases are required for one ALD cycle by supplying the appropriate number of reactors and separating these by gas locks such that the particles can be conveyed from one to the next through one dedicated gas lock.

The apparatus of the present invention is particularly well suited for coating particles by atomic layer deposition. Therefore, the present invention further relates to a process of coating particles by atomic layer deposition, hereinafter also referred to as inventive process. The inventive process includes exposing the particles in a first reactor to a first reactive gas and in a second reactor to a second reactive gas wherein at least one buffer device (c) is involved. The reactive gases and reactors are defined above. The particles are conveyed from the first reactor to the second reactor through a first gas lock and from the second to the first reactor through a second gas lock as described above, preferably some of the particles are conveyed from the first reactor to the second reactor through a first gas lock and simultaneously other parts of the particles are conveyed from the second to the first reactor through a second gas lock. Preferably, the particles are continuously cycled from the first reactor to the second and back to the first. Preferably, the process according to the present invention is performed in the apparatus according to the present invention, in particular in one of the preferred embodiments of the apparatus.

In one embodiment of the inventive process, the particles to be coated have a weight average particle diameter in the range of from 0.1 to 1000 μm, preferably from 0.2 to 500 μm, more preferably from 0.5 to 200 μm, in particular from 1 to 100 μm and even more preferably from 2 to 15 μm. The average particle diameter is preferably measured by dynamic light scattering according to ISO 22412 (2008), preferably by using the Mie theory.

The respective reactions according to the inventive process may be termed self-limiting which means that each reactive gas reacts exhaustively with the active sites of the particles.

Preferably, the reactive gases are each mixed with an inert gas such as nitrogen or argon. The weight ratio of reactive gas to inert gas is preferably from 1:1 to 1:1000, in particular from 1:5 to 1:200, such as 1:10 to 1:50. Preferably, the reactive gas is mixed with the inert gas prior to being introduced to the reactor, e.g. by a bubbler. Preferably, the mixture of reactive gas and inert gas is continuously introduced into the reactor while the particles are also continuously charged to and discharged from the reactor. Preferably, the weight ratio of particles to the mixture of reactive gas and inert gas is 1:1 to 1:100, more preferably 1:5 to 1:50.

The sequence including steps (a) and (b), i.e. (a) exposing the particles in a first reactor to a first gas which reacts with the surface of the particles and (b) exposing the particles in a second reactor to a second gas which reacts with the surface of the particles after having reacted with the first gas, wherein the particles are conveyed from the first reactor to the second reactor through a first gas lock and from the second to the first reactor through a second gas lock—or, in each case optionally, to a buffer device (c)—is typically performed 1 to 1000 times, preferably 2 to 500 times, more preferably 3 to 200 times, in particular 4 to 100 times, such as 5 to 50 times.

In one embodiment of the inventive process the particles are conveyed from the first to the second reactor by pneumatic conveying.

In one embodiment of the present invention, the pressure in the first and the second reactor may be in a wide range, such as from 1 mbar to 10 bar. Preferably, the pressure is close to atmospheric pressure, such as 500 to 1500 mbar, preferably 800 to 1200 mbar, more preferably 900 to 1100 mbar, in particular 950 to 1050 mbar. The pressure in the first and in the second reactor can be the same or different to each other within these ranges.

In one embodiment of the present invention the particle stream rates are at least 10 kg per hour, more preferably at least 20 kg per hour, in particular at least 50 kg per hour, such as at least 100 kg per hour. A suitable upper limit is 15 t/h. The particle stream rate is defined above. The total amount of particles coated per time can thus typically be obtained by dividing the particle stream rate by the number of ALD cycles which is required for the coating.

The temperature in the first and the second reactor can be in a wide range, such as room temperature to 400° C., preferably from 50 to 300° C., more preferably from 80 to 250° C., such as 140 to 220° C. The temperature in the first and the second reactor can be the same or different to each other within these ranges.

The average residence time of the particles in the reactor depends on the reactivity of the reactive gas. Typically, the average residence time is 1 s to 30 min, preferably 30 s to 20 min, such as 1 to 10 min.

Various particles can be coated with the process according to the present invention, including pigments, fillers, catalysts, or cathode active materials for lithium ion batteries. In a preferred embodiment the particles are selected from cathode active materials for lithium ion batteries. Examples of cathode active materials for lithium ion batteries include LiFePO₄, LiNiO₂, LiCoO₂, LiMnO₂, and Li₁₊ₐ(NiₓCo_{y}Mn_{z}M¹_{d})₁₋ₐO₂ with x+y+z+d=1 (“NCM”) and 0≤a≤0.2, and Li(NiₓCo_{y}Al_{z})O₂ (“NCA”) with x+y+z=1.

Preferred are Li₁₊ₐ(NiₓCo_{y}Mn_{z}M¹_{d})₁₋ₓO₂, with M¹ being selected from Ca, Al, Ti, Zr, Zn, Mo, V and Fe, the further variables being defined as follows:

a being in the range of from 0.0 to 0.2, preferably 0.015 to 0.1,

x being in the range of from 0.3 to 0.8,

y being in the range of from zero to 0.35,

z being in the range of from 0.1 to 0.5,

d being in the range of from zero to 0.03,

with x+y+z+d=1.

Further examples of lithiated transition metal oxides are those of the general formula Li_{1+y}M²_{2-y}O₄₋ᵣ.

where r is from zero to 0.4 and y is in the range of from zero to 0.4, and

M² is selected from one or more metals of groups 3 to 12 of the periodic table, for example Ti, V, Cr, Mn, Fe, Co, Ni, Zn, Mo, with Mn, Co and Ni and combinations therefrom being preferred, and especially from combinations of Ni and Mn. Even more preferred are LiMn₂O₄ and LiNi₂₋ₜMnₜO₄ with the variable t being in the range of from zero to 1.

Examples of lithium NCA are compounds of the general formula Li[NiₓCo_{y}Al_{z}]O₂₊ᵣ. Typical values for x, y and z in NCA are:

x is in the range of from 0.8 to 0.9,

y is in the range of from 0.09 to 0.2, and

z is in the range of from 0.01 to 0.05.

r is in the range of from zero to 0.4.

Preferred lithiated transition metal oxides that can be made according to the process according to the present invention are lithiated spinels and NCM.

1-13. (canceled)

14. An apparatus for coating particles by atomic layer deposition, the apparatus comprising:
(a) a first reactor capable of bringing particles in contact with a first reactive gas;
(b) a second reactor capable of bringing particles in contact with a second reactive gas; and
(c) at least one buffer device located between the first and the second reactor,
wherein the first and the second reactor are separated by a first and a second gas lock and the particles can be conveyed from the first reactor through the first gas lock to the second reactor or to a buffer device (c) and at the same time the particles can be conveyed from the second reactor through the second gas lock to the first reactor or to a buffer device (c).

15. The apparatus according to claim 14, wherein first and the second reactor are each equipped with an inlet valve, which is equipped with a gauge to measure the gas flow rate and means to control the flow rate of the reactive gas through the inlet valve.

16. A process for coating particles, comprising:
(a) exposing the particles in a first reactor to a first gas which reacts with the surface of the particles; and
(b) exposing the particles in a second reactor to a second gas which reacts with the surface of the particles after having reacted with the first gas,
wherein the particles are conveyed from the first reactor to the second reactor or to a buffer device (c) through a first gas lock and from the second reactor to the first reactor or to a buffer device (c) through a second gas lock,
wherein at least one buffer device (c) is involved, and
wherein the particle stream rate through the first reactor is higher or lower than the particle stream rate through the second reactor.

17. The process according to claim 16, wherein the pressure in the first and the second reactor is in the range of from 900 to 1100 mbar.

18. The process according to claim 16, wherein first reactive gas is a metal-containing compound.

19. The process according to claim 16, wherein the second reactive gas is water.

20. The process according to claim 16, wherein the sequence including (a) and (b) is performed at least twice.

21. The process according to claim 16, wherein the particles are conveyed from the first to the second reactor by pneumatic conveying.

22. The process according to claim 16, wherein the particles are conveyed at an overall particle stream rate of at least 10 kg per hour.

23. The process according to claim 16, wherein the particles have a weight average particle diameter of 1 to 100 μm, measured by dynamic light scattering according to ISO 22412 (2008).

24. The process according to claim 16, wherein the temperature and the pressure in the first and the second reactor are set independently of each other.

25. The process according to claim 16, wherein the particles are selected from cathode active materials for lithium ion batteries.
